(19) United States
(12) Patent Application Publication
(10) Pub. No.: US 2026/0324424 A1
(43) Pub. Date: Oct. 15, 2026

(54) POWER MODULE AND METHOD MANUFACTURING OF POWER MODULE

(71) Applicants: Hyundai Motor Company, Seoul (KR); Kia Corporation, Seoul (KR)

(72) Inventors: Nam Sik KONG, Hwaseong-si (KR); Sung Taek HWANG, Hwaseong-si (KR); Jun Hee PARK, Hwaseong-si (KR); Se Yoon JEONG, Hwaseong-si (KR)

(73) Assignees: Hyundai Motor Company, Seoul (KR); Kia Corporation, Seoul (KR)

(21) Appl. No.: 19/325,717

(22) Filed: Sep. 11, 2025

(30) Foreign Application Priority Data
Apr. 9, 2025 (KR) 10-2025-0046267

(51) Int. Cl. H01L 23/46; H01L 21/48; H01L 21/56; H01L 23/16; H01L 23/31; H01L 25/07; H10D 80/20

(52) U.S. Cl. CPC H10W 40/40; H10W 40/037; H10W 74/01; H10W 74/114; H10W 76/40; H10W 90/00; H10D 80/251

(57) ABSTRACT

A power module includes a substrate including an insulating layer, a first metal layer provided on one surface of the insulating layer, and a second metal layer provided on the other surface of the insulating layer, an insulating portion provided on one surface of the substrate, the insulating portion having a circuit pattern buried therein, at least one chip mounted on the substrate within the insulating portion, the at least one chip connected to the circuit pattern, and a cooler connected to the substrate, the cooler having at least one cooling groove.

### CROSS-REFERENCE TO RELATED APPLICATION(S)

This application claims benefit of priority to Korean Patent Application No. 10-2025-0046267 filed on Apr. 9, 2025 in the Korean Intellectual Property Office, the disclosure of which is incorporated herein by reference in its entirety.

### TECHNICAL FIELD

The present disclosure relates to a power module and a method of manufacturing the same.

An inverter may be used for motor driving in hybrid vehicles, electric vehicles, or the like. The inverter may convert direct current (DC) power into alternating current (AC) power, or convert AC power into DC power. The inverter may include a power module including a semiconductor chip performing a switching function. During operations of the power module, heat may be generated in the semiconductor chip due to high current. The heat generated in the semiconductor chip may increase temperature of the power module, which may adversely affect operation of the power module. For stable operation of the power module, it may be necessary to externally dissipate heat generated in the semiconductor chip to cool the power module.

As one form of the power module, an embedded power module is used. The embedded power module may refer to a power module in which a power semiconductor device (chip) performing power conversion and supply functions is directly embedded in a printed circuit board (PCB) or substrate.

As a method of cooling a power module, an indirect cooling method and a direct cooling method may be used. The indirect cooling method may be a method of inserting material such as a thermal interface material (TIM) into a space between a substrate and a cooling channel and transferring heat from the substrate to the cooling channel through the inserted material. The direct cooling method may be a method of allowing heat transfer in a state in which a substrate and a cooling channel are directly coupled to each other.

### SUMMARY

An aspect of the present disclosure is to provide a power module advantageous for miniaturization and a method of manufacturing the same.

Another aspect of the present disclosure is to provide a power module having improved cooling performance and a method of manufacturing the same.

According to an aspect of the present disclosure, there is provided a power module including a substrate having an insulating layer, a first metal layer provided on one surface of the insulating layer, and a second metal layer provided on the other surface of the insulating layer, an insulating portion provided on one surface of the substrate, the insulating portion having a circuit pattern buried therein, at least one chip mounted on the substrate within the insulating portion, the at least one chip connected to the circuit pattern, and a cooler connected to the substrate, the cooler having at least one cooling groove.

According to another aspect of the present disclosure, there is provided a method of manufacturing a power module, the method including a chip mounting operation of mounting a chip on one surface of a substrate, an insulating portion forming operation of laminating and curing an insulating sheet on the one surface of the substrate to form an insulating portion, a circuit pattern space forming operation of removing a portion of the insulating portion to form a circuit pattern space, a circuit pattern forming operation of injecting a conductive material into the circuit pattern space to form a circuit pattern, and a cooler fastening operation of fastening a cooler to the other surface of the substrate.

According to example embodiments of the present disclosure, a power module may be miniaturized.

According to example embodiments of the present disclosure, a power module may have improved cooling performance.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view of a power module according to an example embodiment of the present disclosure;

FIG. 2 is a schematic cross-sectional view of a power module according to another example embodiment of the present disclosure;

FIG. 3 is a flowchart of a method of manufacturing a power module according to another example embodiment of the present disclosure;

FIG. 4 is a cross-sectional view of a state in which a chip is mounted on a substrate in a power module manufacturing method according to another example embodiment of the present disclosure;

FIG. 5 is a cross-sectional view of a state in which an insulating portion is formed in a power module manufacturing method according to another example embodiment of the present disclosure;

FIG. 6 is a cross-sectional view of a state in which a circuit pattern space is formed in a power module manufacturing method according to another example embodiment of the present disclosure;

FIG. 7 is a cross-sectional view of a state in which a circuit pattern is formed in a power module manufacturing method according to another example embodiment of the present disclosure;

FIG. 8 is a plan view of the circuit pattern formed in FIG. 7; and

FIG. 9 is a cross-sectional view of a state in which a cooler is coupled to a substrate in a power module manufacturing method according to another example embodiment of the present disclosure.

### DETAILED DESCRIPTION

Various modifications may be made to the example embodiments. Here, the example embodiments are not construed as limited to the disclosure and should be understood to include all changes, equivalents, and replacements within the idea and the technical scope of the disclosure.

The terms such as first, second, A, B, (a), (b), and the like may be used herein to describe components. Each of these terminologies is not used to define an essence, order or sequence of a corresponding component but used merely to distinguish the corresponding component from other component(s). For example, a first component may be referred to a second component, and similarly the second component may also be referred to as the first component. The term “and/or” may include combinations of a plurality of related described items or any of a plurality of related described items.

The terms such as “unit,” “portion,” “part,” and the like may be used to describe various components, but the components should not be limited by the terms. The above-described terms may refer to a term indicating not only a physically/visually distinct component, but also a function or component of a corresponding portion even when not clearly divided or partitioned.

The terminology used herein is for the purpose of describing particular example embodiments only and is not to be limiting of the example embodiments. As used herein, the singular forms “a,” “an,” and “the” are intended to include the plural forms as well, unless the context clearly indicates otherwise. As used herein, the term “and/or” includes any one and any combination of any two or more of the associated listed items. It will be further understood that the terms “comprises” and/or “comprising,” when used in this disclosure, specify the presence of stated features, integers, operations, operations, elements, components or a combination thereof, but do not preclude the presence or addition of one or more other features, integers, operations, operations, elements, components, and/or groups thereof.

Unless otherwise defined herein, all terms used herein, including technical or scientific terms, have the same meanings as those generally understood by one of ordinary skill in the art. Terms defined in dictionaries generally used should be construed to have meanings matching contextual meanings in the related art and are not to be construed as having an ideal or excessively formal meaning, unless otherwise defined herein.

In the description below, the terms “front,” “rear,” “upper,” “lower,” “top,” “bottom,” and the like used in relation to directions are defined based on the drawings.

Hereinafter, preferred example embodiments of the present disclosure will be described in more detail with reference to the accompanying drawings.

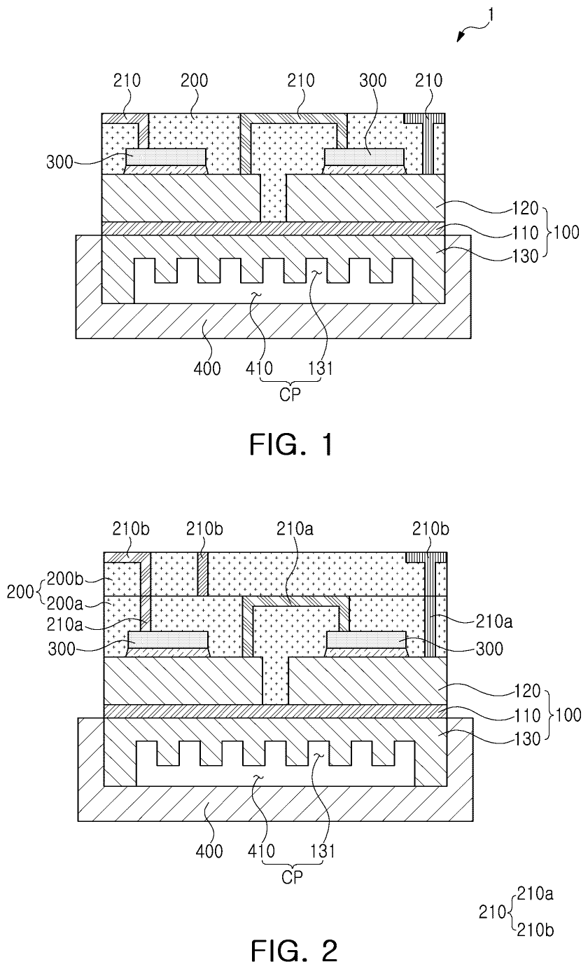

FIG. 1 is a schematic cross-sectional view of a power module according to an example embodiment of the present disclosure. Referring to FIG. 1, a power module 1 according to an example embodiment of the present disclosure may include a substrate 100, an insulating portion 200, a chip 300, and a cooler 400.

The substrate 100 may include an insulating layer 110, a first metal layer 120, and a second metal layer 130. The insulating layer 110 may include at least one of ceramic or a polymer resin. For example, the insulating layer 110 may include at least one of alumina, aluminum nitride, silicon nitride, epoxy, or polyimide. The insulating layer 110 may be provided, for example, in the form of a plate.

A first metal layer 120 may be provided on one surface of the insulating layer 110. The first metal layer 120 may include a plurality of circuit lines. The circuit lines of the first metal layer 120 may be electrically connected to at least one of the chip 300, a power lead, or a signal lead. For example, the first metal layer 120 may be electrically connected to at least one of the chip 300, the power lead, or the signal lead through a circuit pattern 210 formed in the insulating portion 200. The power lead may be formed of a conductive material electrically connected to the chip 300 to supply power to the chip 300 or to output power converted by the chip 300. The signal lead may be formed of a conductive material electrically connected to the chip 300 to input a control signal to the chip 300 or to receive state information of the chip 300. The first metal layer 120 may be provided as a conductor having high electrical conductivity. For example, the first metal layer 120 may include at least one of copper, aluminum, silver, or nickel. The first metal layer 120 may be formed using a lamination, deposition, or plating method. The method of forming the first metal layer 120 may be replaced with various methods commonly used in the technical field to which the present disclosure pertains.

A second metal layer 130 may be provided on the other surface of the insulating layer 110. Here, a ratio of a volume (v1) of the first metal layer 120 to a volume (v2) the second metal layer 130, that is, a volume ratio, may be 1:1. Here, the volume (v1) of the first metal layer 120 may be a volume of a space formed by an external edge of the first metal layer 120. The volume v2 of the second metal layer 130 may be a volume of a space defined by an external edge of the second metal layer 130. The volume ratio of the first metal layer 120 to the second metal layer 130, which is formed as 1:1, may minimize warpage of the substrate 100.

The cooler 400 may be connected to the second metal layer 130. For example, the cooler 400 may be connected to the second metal layer 130 such that at least a portion of the second metal layer 130 is provided in a cooling groove 410 of the cooler 400. When the chip 300 mounted on the substrate 100 operates, heat may be generated. The heat generated in the chip 300 may be transferred to the second metal layer 130. The heat generated from the chip 300 may be dissipated externally through the second metal layer 130. The second metal layer 130 may be provided as a conductor having high thermal conductivity. For example, the second metal layer 130 may include at least one of copper or aluminum. The second metal layer 130 may be formed using a lamination, deposition, or plating process. The method of forming the second metal layer 130 may be replaced by various methods commonly used in the technical field to which the present disclosure pertains.

At least one auxiliary cooling groove 131 may be provided in the second metal layer 130. The auxiliary cooling groove 131 may be provided in an external surface of the second metal layer 130. For example, the auxiliary cooling groove 131 may be provided in one surface of the second metal layer 130, not opposing the insulating layer 110. The auxiliary cooling groove 131 may be formed by a portion of the one surface of the second metal layer 130 being recessed inwardly by a predetermined depth. When the cooler 400 is connected to the substrate 100, the auxiliary cooling groove 131 may be connected to the cooling groove 410 of the cooler 400. The auxiliary cooling groove 131 may form a cooling path CP in which a coolant flows, together with the cooling groove 410 provided in the cooler 400.

The insulating portion 200 may be provided on one surface of the substrate 100. The insulating portion 200 may be provided as a prepreg. The prepreg may be an intermediate base material for fiber-reinforced composite materials, which has excellent flowability and adhesiveness in a semi-cured state and is thus used as an adhesive layer or insulating material layer. For example, the prepreg, a molding material in which a matrix resin is preliminarily impregnated into a reinforcing fiber, may be an adhesive sheet in which a resin (BT/Epoxy, FR4, FR5, or the like) is impregnated into a glass fiber. In addition, the insulating portion 200 may be a thermosetting or thermoplastic polymer substrate, a ceramic substrate, an organic/inorganic composite material substrate, or a glass fiber-impregnated substrate. When the insulating portion 200 includes a polymer resin, the insulating portion 200 may include an epoxy-based insulating resin or a polyimide-based resin.

A circuit pattern 210 may be provided in the insulating portion 200. The circuit pattern 210 may electrically connect the chip 300 and the lead portion to each other, that is, the chip 300 and the power lead to each other or the chip 300 and the signal lead to each other. The circuit pattern 210 may be embedded in the insulating portion 200. For example, at least a portion of the circuit pattern 210 may be provided on the inside of the insulating portion 200. A portion of the circuit pattern 210 may be exposed to one surface of the insulating portion 200. For example, with reference to FIG. 1, the circuit pattern 210 may be exposed to an upper surface of the insulating portion 200. The power lead or the signal lead may be connected to the circuit pattern exposed to the one surface of the insulating portion 200. For example, the circuit pattern exposed to the one surface of the insulating portion 200 may be coupled or wire-bonded to the power lead or the signal lead using a conductive member such as a bus bar.

At least one chip 300 may be mounted on the substrate 100. For example, the chip 300 may be mounted on the first metal layer 120 of the substrate 100. The chip 300 may be provided in the insulating portion 200. In other words, the chip 300 may be buried in the insulating portion 200. For example, an external surface of the chip 300 may be surrounded by the insulating portion 200. The chip 300 may be electrically connected to the first metal layer 120 and the circuit pattern 210. The first metal layer 120 and the circuit pattern 210 may form a circuit line for driving the power module 1. The chip 300 may be buried in the insulating portion 200 and connected to the circuit pattern 210 buried in the insulating portion 200, such that the power module 1 according to an example embodiment of the present disclosure may be advantageous for miniaturization.

The chip 300 may include at least one of an insulated gate bipolar transistor (IGBT), a compound semiconductor (SiC), a classification circuit, a silicon-controlled rectifier (SCR), a power transistor, a MOS transistor, a power rectifier, a power regulator, or a diode. The chip 300 may be connected to the power lead and the signal lead. For example, the chip 300 may be connected to the power lead and the signal lead through at least one of the first metal layer 120 or the circuit pattern 210. The chip 300 may be a switching device. The chip 300 may convert power supplied through the power lead and output the converted power. For example, the chip 300 may receive direct current (DC), convert the DC into AC, and output the AC, or may receive AC, convert the AC into DC, and output the DC.

The cooler 400 may be connected to the substrate 100. For example, the cooler 400 may be connected to a portion of the substrate 100 in which the second metal layer 130 is provided. A sealing member for watertightness may be provided between the cooler 400 and the substrate 100. The cooler 400 may include a cooling groove 410. The cooling groove 410 may form a cooling flow path CP in which a coolant flows, together with the auxiliary cooling groove 131 formed in the substrate 100. A cooling fluid may flow in the cooling flow path.

In the power module 1 according to an example embodiment of the present disclosure, the second metal layer 130 of the substrate 100 may be provided as a portion of the cooling flow path CP, such that a distance between the chip 300 and the coolant and the cooler 400 may be reduced, thereby improving cooling performance of the power module 1. In addition, the auxiliary cooling groove 131 may be formed in the second metal layer 130, such that a surface area in contact with the cooling fluid (coolant) may be increased, thereby improving cooling performance of the power module 1. As the power module 1 has improved cooling performance, deformation of the substrate 100 caused by heat may be minimized.

FIG. 2 is a schematic cross-sectional view of a power module 1 according to another example embodiment of the present disclosure. Referring to FIG. 2, the power module 1 according to another example embodiment of the present disclosure may include a substrate 100, an insulating portion 200, a chip 300, and a cooler 400. The power module 1 according to another example embodiment of the present disclosure, illustrated in FIG. 2, may be substantially the same as the power module according to an example embodiment of the present disclosure illustrated in FIG. 1, except for a configuration of an insulating portion 200. Accordingly, detailed descriptions of the same configurations are omitted and replaced with the above descriptions.

An insulating portion 200 may be provided on one surface of the substrate 100. The insulating portion 200 may be provided as a prepreg. The prepreg may be an intermediate base material for fiber-reinforced composite materials, which has excellent flowability and adhesiveness in a semi-cured state and is thus used as an adhesive layer or insulating material layer. For example, the prepreg, a molding material in which a matrix resin is preliminarily impregnated into a reinforcing fiber, may be an adhesive sheet in which a resin (BT/Epoxy, FR4, FR5, or the like) is impregnated into a glass fiber. In addition, the insulating portion 200 may be a thermosetting or thermoplastic polymer substrate, a ceramic substrate, an organic/inorganic composite material substrate, or a glass fiber-impregnated substrate. When the insulating portion 200 includes a polymer resin, the insulating portion 200 may include an epoxy-based insulating resin or a polyimide-based resin.

A circuit pattern 210 may be provided in the insulating portion 200. The circuit pattern 210 may electrically connect the chip 300 and a lead portion to each other, that is, the chip 300 and a power lead to each other or the chip 300 and a signal lead to each other. The circuit pattern 210 may be buried in the insulating portion 200.

The insulating portion 200 may include a plurality of insulating part layers 200a and 200b. The plurality of insulating part layers 200a and 200b may have opposing surfaces bonded to each other. Although FIG. 2 illustrates a configuration in which two insulating part layers 200a and 200b are bonded to each other, the number of insulating part layers is not limited thereto, and the insulating portion 200 may include three or more insulating part layers depending on a structural need or design need.

The plurality of insulating part layers 200a and 200b may include circuit pattern parts 210a and 210b, respectively. The circuit pattern parts 210a and 210b formed in the plurality of insulating part layers 200a and 200b may form the circuit pattern 210. For example, the circuit pattern part 210a formed in one insulating part layer 200a, among the plurality of insulating part layers, may be electrically connected to at least one of the first metal layer 120, the chip 300, or the circuit pattern part 210b formed in the adjacent insulating part layer 200b, so as to form the circuit pattern 210.

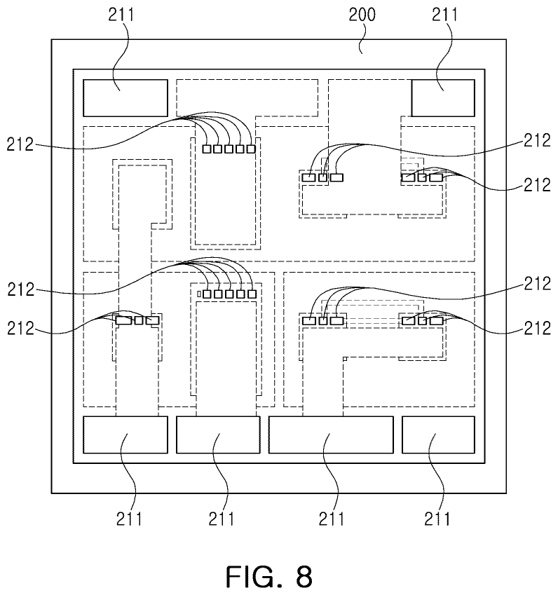

At least a portion of the circuit pattern 210 may be exposed to one surface of an uppermost insulating part layer 200b, among the plurality of insulating part layers 200a and 200b. The circuit pattern 210 exposed to the one surface of the uppermost insulating part layer 200b may include a power lead bonding part 211 (see FIG. 8) and a signal lead bonding part 212 (see FIG. 8). The power lead bonding part 211 and the signal lead bonding part 212 may be connected to the power lead and the signal lead, respectively.

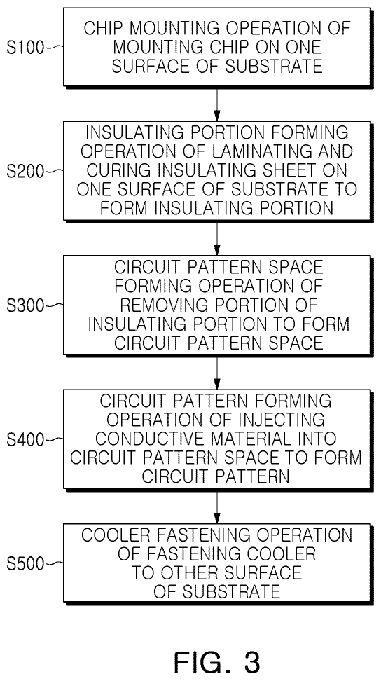

FIG. 3 is a flowchart of a method of manufacturing a power module according to another example embodiment of the present disclosure. Referring to FIG. 3, the method of manufacturing a power module according to another example embodiment of the present disclosure may include a chip mounting operation (S100), an insulating portion forming operation (S200), a circuit pattern space forming operation (S300), a circuit pattern forming operation (S400), and a cooler fastening operation (S500).

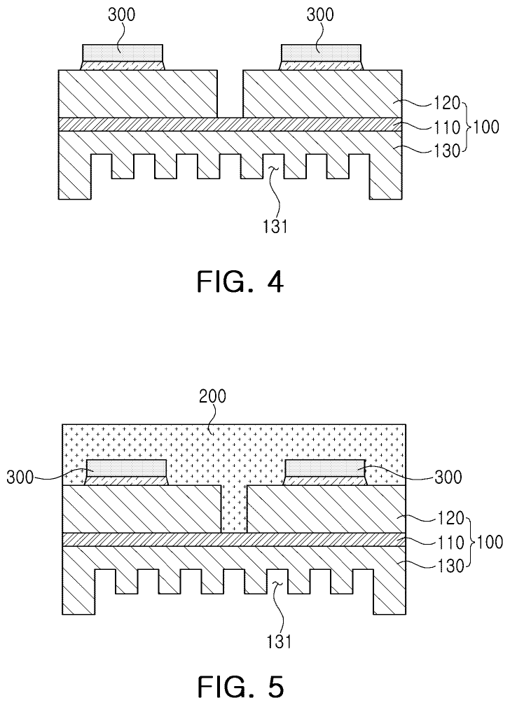

Referring to FIG. 4, in the chip mounting operation (S100), a chip 300 may be mounted on a substrate 100. As a method of mounting the chip 300 on the substrate 100, various methods generally used in the technical field to which the present disclosure pertains, such as sintering and soldering, may be used. The substrate 100 may include an insulating layer 110, a first metal layer 120 provided on one surface of the insulating layer 110, and a second metal layer 130 provided on the other surface of the insulating layer 110. The chip 300 may be mounted on one surface of the substrate 100 on which the first metal layer 120 is provided. The chip 300 may be electrically connected to a circuit line formed on the first metal layer 120. The second metal layer 130 may have at least one auxiliary cooling groove 131. The auxiliary cooling groove 131 may form a cooling flow path CP in which a coolant flows, together with a cooling groove 410 provided in a cooler 400 to be described below.

Referring to FIG. 5, after a chip 300 is mounted on a substrate 100, the insulating portion forming operation (S200) may be performed. In the insulating portion forming operation (S200), an insulating portion 200 may be formed. For example, the insulating portion 200 may be formed by laminating and curing an insulating sheet on the substrate 100. The insulating sheet may be, for example, a prepreg sheet. In other words, the insulating portion 200 may be provided as a prepreg. The prepreg, a molding material in which a matrix resin is preliminarily impregnated into a reinforcing fiber, and may be, for example, an adhesive sheet in which a resin (BT/Epoxy, FR4, FR5, or the like) is impregnated into a glass fiber. The insulating portion 200 may be formed to cover one surface of the substrate 100 and the chip 300.

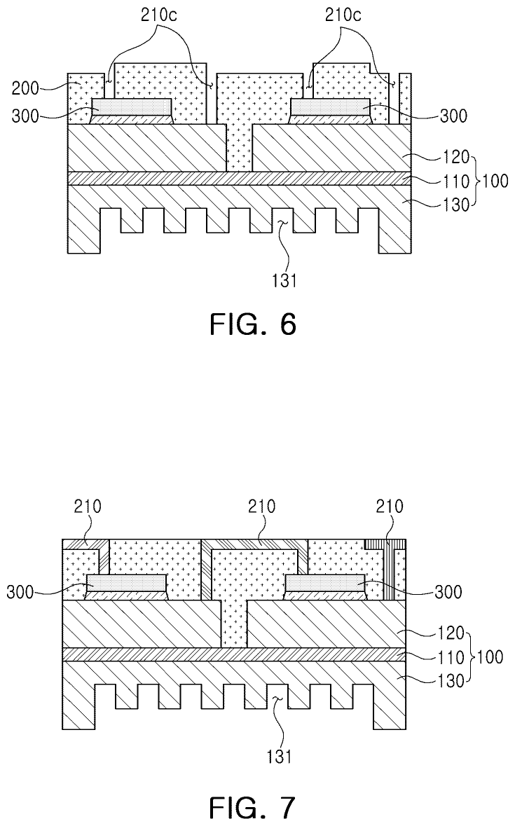

Referring to FIG. 6, after the insulating portion 200 is formed, the circuit pattern space forming operation (S300) may be performed. In the circuit pattern space forming operation (S300), a circuit pattern space 200c may be formed. The circuit pattern space 200c may be formed by removing a portion of the insulating portion 200. For example, the circuit pattern space 200c may be formed by cutting and drilling the insulating portion 200. The circuit pattern space 200c may have a shape corresponding to that of a circuit pattern 210 (see FIG. 7) to be formed in the insulating portion 200.

The circuit pattern space 200c may be provided as a plurality of divided regions. A portion of the circuit pattern space 200c may be connected to the chip 300. The other portion of the circuit pattern space 200c may be connected to the substrate 100.

Referring to FIGS. 7 and 8, after the circuit pattern space 200c is formed, the circuit pattern forming operation (S400) may be performed. In the circuit pattern forming operation (S400), a circuit pattern 210 may be formed in the insulating portion 200. The circuit pattern 210 may be formed by injecting a conductive material into the circuit pattern space 200c. For example, the conductive material may be copper (Cu). The circuit pattern 210 may be electrically connected to the chip 300 or the substrate 100. At least a portion of the circuit pattern 210 may be exposed to one surface of the insulating portion 200. The circuit pattern 210 exposed to the one surface of the insulating portion 200 may include a power lead bonding part 211 and a signal lead bonding part 212. The power lead bonding part 211 and the signal lead bonding part 212 may be connected to a power lead and a signal lead, respectively.

The insulating part forming operation (S200), the circuit pattern space forming operation (S300), and the circuit pattern forming operation (S400) may be performed repeatedly a plurality of times. In this case, the insulating portion 200 may have a shape in which a plurality of layers are bonded to each other (see FIG. 2). A circuit pattern may be formed on each of the plurality of layers, and the circuit patterns formed on the plurality of layers may be electrically connected to the chip.

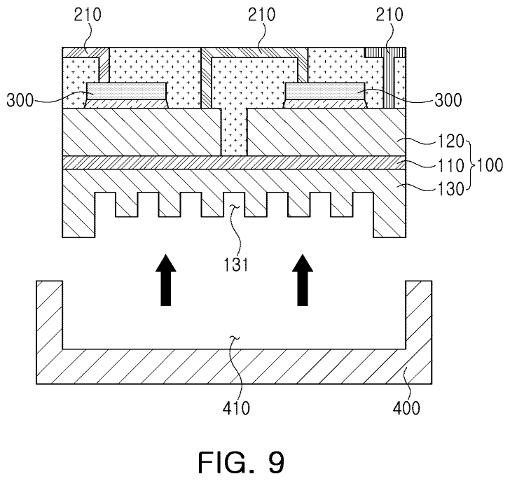

Referring to FIG. 9, after the circuit pattern 210 is formed, the cooler coupling operation (S500) may be performed. In the cooler fastening operation (S500), the cooler 400 may be fastened to the substrate 100. The cooler 400 may be coupled to a portion of the substrate 100 in which the second metal layer 130 is provided. At least a portion of the second metal layer 130 may be disposed in the cooling groove 410 of the cooler 400. The auxiliary cooling groove 131 of the second metal layer 130 may form the cooling flow path CP, together with the cooling groove 410 of the cooler 400.

While example embodiments have been shown and described above, it will be apparent to those skilled in the art that modifications and variations could be made without departing from the scope of the present disclosure as defined by the appended claims.

What is claimed is:

1. A power module comprising:
a substrate including an insulating layer, a first metal layer provided on one surface of the insulating layer, and a second metal layer provided on the other surface of the insulating layer;
an insulating portion provided on one surface of the substrate, the insulating portion having a circuit pattern buried therein;
at least one chip mounted on the substrate within the insulating portion, the at least one chip connected to the circuit pattern; and
a cooler connected to the substrate, the cooler having at least one cooling groove.

2. The power module of claim 1, wherein
at least one auxiliary cooling groove is provided in an external surface of the second metal layer, and the auxiliary cooling groove forms a cooling flow path, together with the cooling groove.

3. The power module of claim 1, wherein a volume ratio of the first metal layer to the second metal layer is 1:1.

4. The power module of claim 1, wherein the insulating portion includes a plurality of laminated insulating part layers.

5. The power module of claim 4, wherein each of the plurality of insulating part layers includes a circuit pattern part, forming the circuit pattern.

6. The power module of claim 4, wherein at least a portion of the circuit pattern is exposed to one surface of an uppermost insulating part layer, among the plurality of insulating part layers.

7. The power module of claim 6, wherein a lead portion is connected to the circuit pattern exposed to the one surface of the insulating part layer.

8. The power module of claim 1, wherein the insulating portion is provided as a prepreg.

9. A method of manufacturing a power module, the method comprising:
a chip mounting operation of mounting a chip on one surface of a substrate;
an insulating portion forming operation of laminating and curing an insulating sheet on the one surface of the substrate to form an insulating portion;
a circuit pattern space forming operation of removing a portion of the insulating portion to form a circuit pattern space;
a circuit pattern forming operation of injecting a conductive material into the circuit pattern space to form a circuit pattern; and
a cooler fastening operation of fastening a cooler to the other surface of the substrate.

10. The method of claim 9, wherein in the insulating portion forming operation, the insulating sheet is provided as a prepreg sheet.

11. The method of claim 9, wherein in the circuit pattern space forming operation, a portion of the circuit pattern space is connected to the chip, and the other portion of the circuit pattern space is connected to the substrate.

12. The method of claim 9, wherein the circuit pattern of the circuit pattern forming operation is exposed to one surface of the insulating portion.

13. The method of claim 9, wherein the insulating portion forming operation, the circuit pattern space forming operation, and the circuit pattern forming operation are repeatedly performed a plurality of times, and the insulating portion has a shape in which a plurality of layers are bonded to each other.

14. The method of claim 13, wherein the circuit pattern is formed on each of the plurality of layers, and the circuit patterns formed on the plurality of layers are electrically connected to the chip.

15. The method of claim 9, wherein
the substrate includes an insulating layer, a first metal layer provided on one surface of the insulating layer, and a second metal layer provided on the other surface of the insulating layer, and
in the cooler fastening operation, the cooler is connected to a portion of the substrate in which the second metal layer is provided.

16. The power module of claim 1, wherein the first metal layer includes copper, aluminum, silver, or nickel.

17. The method of claim 15, wherein the first metal layer includes copper, aluminum, silver, or nickel.

18. The power module of claim 1, wherein the insulating portion includes a thermosetting or thermoplastic polymer substrate, a ceramic substrate, an organic/inorganic composite material substrate, or a glass fiber-impregnated substrate.

19. The method of claim 9, wherein the insulating portion includes a thermosetting or thermoplastic polymer substrate, a ceramic substrate, an organic/inorganic composite material substrate, or a glass fiber-impregnated substrate.
